(19) United States
(12) Patent Application Publication
(10) Pub. No.: US 2017/0115370 A1
(43) Pub. Date: Apr. 27, 2017

(54) APPARATUS AND METHOD OF DIAGNOSING CURRENT SENSOR OF ECO-FRIENDLY VEHICLE

(71) Applicant: Hyundai Motor Company, Seoul (KR)

(72) Inventors: Jung Moon Chang, Suwon (KR); Do Sung Hwang, Gunpo (KR)

(21) Appl. No.: 15/164,433

(22) Filed: May 25, 2016

(30) Foreign Application Priority Data
Oct. 26, 2015 (KR) 10-2015-0149020

(51) Int. Cl. G01R 35/00; B60L 11/18

(52) U.S. Cl. CPC G01R 35/005; B60L 11/1861; B60L 11/1851

(57) ABSTRACT

An apparatus and a method of diagnosing a current sensor of an eco-friendly vehicle is provided. A fault is detected in a current range between disconnection and short-circuit of a current sensor by monitoring whether a load using a high voltage in the eco-friendly vehicle is operated to detect a fault of the current sensor sensing an output current of a high voltage battery. The apparatus includes the current sensor configured to sense an output current of a high voltage battery and a load monitor that monitors whether a load in the eco-friendly vehicle is operated. A controller then detects an abnormality in the current sensor when the current sensor senses a current exceeding a first threshold value and the load is not operated.

### CROSS-REFERENCE TO RELATED APPLICATION

This application is based on and claims the benefit of priority to Korean Patent Application No. 10-2015-0149020, filed on Oct. 26, 2015 in the Korean Intellectual Property Office, the disclosure of which is incorporated herein in its entirety by reference.

### TECHNICAL FIELD

The present disclosure relates to an apparatus and a method of diagnosing a current sensor of an eco-friendly vehicle, and more particularly, to a technology of diagnosing whether a fault occurs in a current sensor for a high voltage battery by monitoring an operation of a load using a high voltage in an eco-friendly vehicle.

### BACKGROUND

Generally, an eco-friendly vehicle includes an engine, a driving motor assisting in the engine, and a high voltage battery that drives the driving motor. Particularly, the driving motor and the high voltage battery are electrically connected by a motor inverter and a main relay. In addition, the eco-friendly vehicle includes a current sensor installed in the high voltage battery to sense an output current of the high voltage battery, and a battery management system (BMS) that is configured to calculate a state of charge (SOC) of the battery based on the output current.

Further, a hybrid control unit (HCU) is used as a main factor in distributing power of the vehicle with reference to the SOC of the BMS. In other words, the HCU determines a power assist amount based on a driver requirement with reference to the SOC of the BMS. For example, the HCU increases the power assist amount when the SOC is high and decreases the power assist amount when the SOC is low. Particularly, a failure or error of the current sensor may be divided into disconnection and short-circuit of a hard wire (a power line) between the BMS and the current sensor, and other faults.

An apparatus of diagnosing a current sensor of an eco-friendly vehicle according to the related art may diagnose only disconnection (e.g., about −400 A) and short-circuit (e.g., about +400 A) of the power line of the current sensor, and may not diagnose a fault other than the disconnection and the short-circuit, that is, an error in which an abnormal current value is sensed in a current range (e.g., about −400 A to +400 A). Therefore, the BMS calculates the SOC based on an inaccurate current value, and the HCU controls a hybrid based on the basis erroneously calculated SOC, which causes a fault of the high voltage battery.

For example, when the SOC is actually low, but is erroneously calculated to be high, the HCU requires a power assist amount greater than when the SOC is low by the driver requirement, and energy corresponding to the greater power assist amount is supplied from the high voltage battery. In particular, since a substantial amount of energy is supplied from the high voltage battery when the SOC of the high voltage battery is actually low, the high voltage battery may be excessively discharged, which may cause the high voltage battery to fail.

### SUMMARY

The present disclosure provides an apparatus and a method of diagnosing a current sensor of an eco-friendly vehicle capable of diagnosing a fault occurring in a current range between disconnection and short-circuit of a current sensor by monitoring whether a load using a high voltage in the eco-friendly vehicle is operated to diagnose a fault of the current sensor sensing an output current of a high voltage battery.

Objects of the present disclosure are not limited to the above-mentioned object, and other objects and advantages of the present disclosure that are not mentioned may be understood by the following description and will be more clearly appreciated by exemplary embodiments of the present disclosure. In addition, it may be easily appreciated that objects and advantages of the present disclosure may be realized by means mentioned in the claims and a combination thereof.

According to an exemplary embodiment of the present disclosure, an apparatus of diagnosing a current sensor of an eco-friendly vehicle may include: the current sensor configured to sense an output current of a high voltage battery; a load monitor configured to monitor whether a load in the eco-friendly vehicle is operated; and a controller configured to diagnose that an abnormality is present in the current sensor when the current sensor senses a current exceeding a first threshold value and when the load is not operated. The load may be any one of a driving motor, a low voltage direct current (DC) to DC converter (LDC), an inverter, an air conditioner compressor, and an on-board charger. The controller may be configured to reset the current sensor in response to determining that the abnormality is present in the current sensor.

The apparatus of diagnosing a current sensor of an eco-friendly vehicle may further include a voltage sensor configured to sense a voltage of the high voltage battery. The controller may be configured to diagnose that the abnormality is present in the load when a voltage variation of the high voltage battery exceeds a second threshold value for a threshold period of time and diagnose that the abnormality is present in the current sensor when the voltage variation of the high voltage battery is less than the second threshold value for the threshold period of time, when the current sensor senses the current exceeding the first threshold value and when the load is not operated.

According to another exemplary embodiment of the present disclosure, a method of diagnosing a current sensor of an eco-friendly vehicle may include: monitoring, by a load monitor, whether a load in the eco-friendly vehicle is operated; sensing, by the current sensor, an output current of a high voltage battery; and diagnosing, by a controller, that an abnormality is present in the current sensor when the current sensor senses a current exceeding a first threshold value and when the load is not operated. The load may be any one of a driving motor, a low voltage direct current (DC) to DC converter (LDC), an inverter, an air conditioner compressor, and an on-board charger. The method of diagnosing a current sensor of an eco-friendly vehicle may further include resetting the current sensor in response to determining that the abnormality is present in the current sensor.

According to still another exemplary embodiment of the present disclosure, a method of diagnosing a current sensor of an eco-friendly vehicle may include: monitoring, by a load monitor, whether a load in the eco-friendly vehicle is operated; sensing, by the current sensor, an output current of a high voltage battery; sensing, by a voltage sensor, a voltage of the high voltage battery; and diagnosing, by a controller, that an abnormality is present in the current sensor based on the voltage sensed by the voltage sensor when the current sensor senses a current exceeding a first threshold value and when the load is not operated.

The diagnosing may include: monitoring a voltage variation of the high voltage battery for a threshold period of time when the current sensor senses the current exceeding the first threshold value and when the load is not operated; diagnosing that the abnormality is present in the current sensor when the voltage variation is less than a second threshold value; and diagnosing that abnormality is present in the load when the voltage variation exceeds the second threshold value. The method of diagnosing a current sensor of an eco-friendly vehicle may further include resetting the current sensor in response to determining that the abnormality is present in the current sensor.

### BRIEF DESCRIPTION OF THE DRAWINGS

The above and other objects, features and advantages of the present disclosure will be more apparent from the following detailed description taken in conjunction with the accompanying drawings.

FIG. 1 is a block diagram illustrating an apparatus of diagnosing a current sensor of an eco-friendly vehicle according to an exemplary embodiment of the present disclosure;

FIG. 2 is a flow chart illustrating a method of diagnosing a current sensor of an eco-friendly vehicle according to an exemplary embodiment of the present disclosure; and

FIG. 3 is a flow chart illustrating a method of diagnosing a current sensor of an eco-friendly vehicle according to another exemplary embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/of” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Furthermore, control logic of the present invention may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The above-mentioned objects, features, and advantages will become more obvious from the following description described below in detail with reference to the accompanying drawings. Therefore, those skilled in the art to which the present disclosure pertains may easily practice a technical idea of the present disclosure. Further, in describing the present disclosure, in the case in which it is decided that a detailed description of a well-known technology associated with the present disclosure may unnecessarily make the gist of the present disclosure unclear, it will be omitted. Hereinafter, exemplary embodiments of the present disclosure will be described in detail with reference to the accompanying drawings.

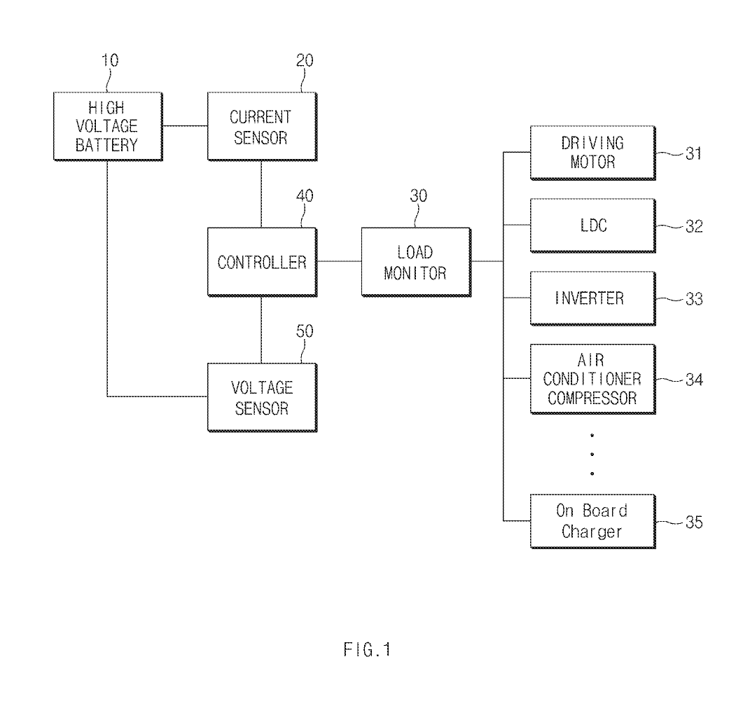

FIG. 1 is a block diagram illustrating an apparatus of diagnosing a current sensor of an eco-friendly vehicle according to an exemplary embodiment of the present disclosure. As illustrated in FIG. 1, the apparatus of diagnosing a current sensor of an eco-friendly vehicle according to an exemplary embodiment of the present disclosure may include a high voltage battery 10, a current sensor 20, a load monitor 30, and a controller 40. The respective components described above will be described.

First, the high voltage battery 10, mounted within an eco-friendly vehicle to supply a high voltage, may be charged by a driving motor (not illustrated). The current sensor 20 may be configured to sense an output current of the high voltage battery 10. Further, the current sensor 20 may be configured to sense a current of, about −400 A as an output current when disconnection occurs in a power line and may be configured to sense a current of, about, +400 A as an output current when short-circuit occurs in the power line. In addition, the current sensor 20 may be configured to sense a current in a predetermined range (e.g., about −400 A to +400 A) when the disconnection or the short-circuit does not occur.

The load monitor 30 may then be configured to monitor whether a load of the eco-friendly vehicle is operated. Particularly, the load may be any one of a driving motor 31 configured to receive a high voltage supplied from the high voltage battery 10 to drive the vehicle, a low voltage direct current (DC) to DC converter (LDC) 32 configured to convert the high voltage of the high voltage battery 10 into a low voltage for an electric load, an inverter 33 configured to convert DC into DC, an air conditioner compressor 34, and an on-board charger 35 configured to boost external alternating current (AC) power and convert the external AC power into DC power to charge the high voltage battery, during on-board charging.

Additionally, the controller 40 may be configured to diagnose or detect an abnormality in the current sensor 20 when the current sensor 20 senses a current exceeding a threshold value (e.g., about 10 A) and when the load is not operated. For example, in a hybrid bus in which the driving motor charges/discharges the high voltage battery 10, the controller 40 may be configured to detect an abnormality in the current sensor 20 when the current sensor 20 senses a current exceeding about 10 A and when the driving motor 31 is not operated (e.g., a state in which a revolution per minute (RPM) of the driving motor is about 10 or less). In addition, the controller 40 may be configured to reset the current sensor 20 to solve the abnormality of the current sensor 20 in response to detecting the abnormality in the current sensor 20.

Meanwhile, the apparatus of diagnosing a current sensor of an eco-friendly vehicle according to an exemplary embodiment of the present disclosure may further include a voltage sensor 50 configured to sense a voltage of the high voltage battery 10. In particular, the controller 40 may also be configured to determine whether the abnormality is present in the current sensor 20 using the voltage sensed by the voltage sensor 50, when the current sensor 20 senses the current is greater than about 10 A and the driving motor 31 is not operated (e.g., the state in which the RPM of the driving motor is about 10 or less).

In other words, the controller 40 may be configured to detect the abnormality in the driving motor 31 when a voltage variation of the high voltage battery 10 is greater than about 5V and detect the abnormality in the current sensor 20 when the voltage variation of the high voltage battery 10 is less than about 5V, when the current sensor 20 senses the current exceeding about 10 A and when the driving motor 31 is not operated (e.g., the state in which the RPM of the driving motor is about 10 or less).

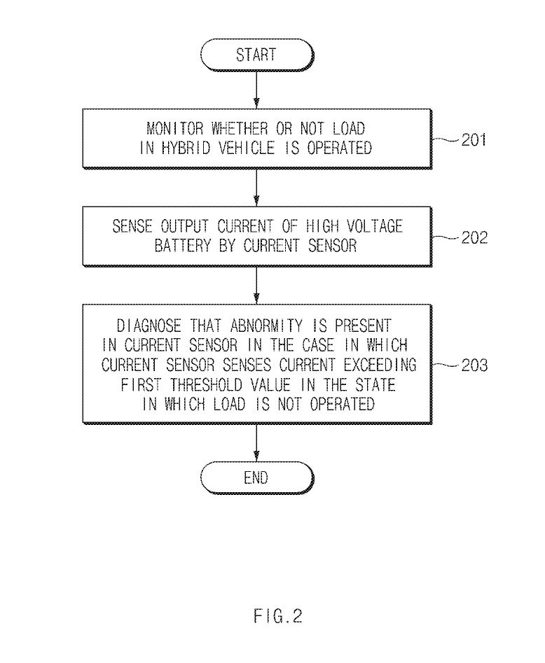

FIG. 2 is a flow chart illustrating a method of diagnosing a current sensor of an eco-friendly vehicle according to an exemplary embodiment of the present disclosure. First, the load monitor 30 may be configured to monitor whether the load in the eco-friendly vehicle is operated (201). Then, the current sensor may be configured to sense the output current of the high voltage battery 10 (202). Further, when the current sensor senses a current that is greater a first threshold value when the load is not operated, the controller 40 may be configured to detect the abnormality in the current sensor 20 (203). Particularly, the load may be any one of the driving motor, the LDC, the inverter, the air conditioner compressor, and the on-board charger. Then, the controller 40 may be configured to reset the current sensor 20 in response to detecting the abnormality in the current sensor 20.

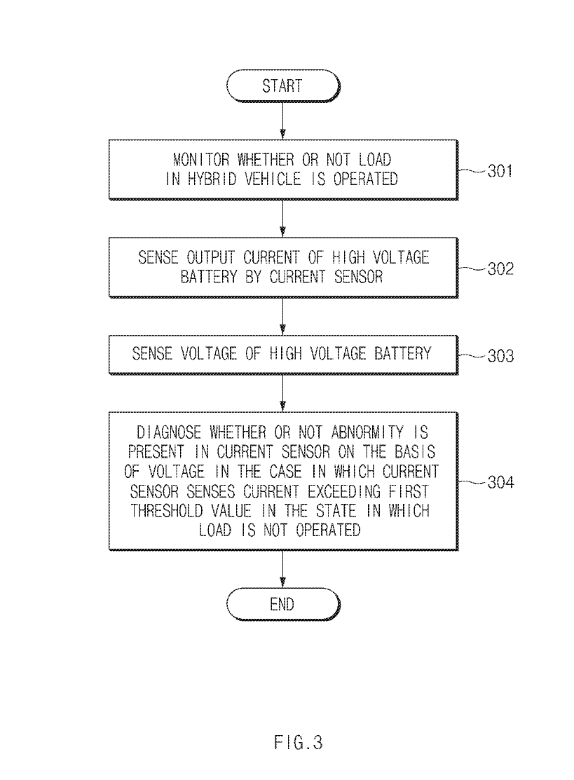

FIG. 3 is a flow chart illustrating a method of diagnosing a current sensor of an eco-friendly vehicle according to another exemplary embodiment of the present disclosure. First, the load monitor 30 may be configured to monitor whether the load in the eco-friendly vehicle is operated (301). Then, the current sensor 20 may be configured to sense the output current of the high voltage battery 10 (302). The voltage sensor 50 may be configured to sense the voltage of the high voltage battery 10 (303).

Furthermore, when the current sensor senses a current exceeding a first threshold value and the load is not operated, the controller 40 may be configured to determine whether the abnormality is present in the current sensor 20 based on the voltage sensed by the voltage sensor 50 (304). In other words, the controller 40 may be configured to detect the abnormality in the load when a voltage variation of the high voltage battery is greater than a second threshold value for a threshold period of time and detect the abnormality in the current sensor when the voltage variation of the high voltage battery is less than the second threshold value for the threshold period of time, when the current sensor senses the current exceeding the first threshold value and the load is not operated. Then, the controller 40 may be configured to reset the current sensor 20 in response to detecting the abnormality in the current sensor 20.

Moreover, the method of diagnosing a current sensor of an eco-friendly vehicle according to the present disclosure as described above may be executed by a computer program. In addition, codes and code segments configuring the computer program may be easily inferred by a computer programmer skilled in the related art. Further, the created computer program may be stored in a computer-readable recording medium (information storing medium) and may be read and executed by a computer to implement the method of diagnosing a current sensor of an eco-friendly vehicle according to the present disclosure. The computer-readable recording medium includes all types of recording media that are readable by the computer.

As described above, according to the exemplary embodiment of the present disclosure, whether the load using a high voltage in the eco-friendly vehicle is operated may be monitored to diagnose a fault of the current sensor configured to sense the output current of the high voltage battery, thereby making it possible to diagnose a fault occurring in a current range between the disconnection and the short-circuit of the current sensor.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. An apparatus of diagnosing a current sensor of an eco-friendly vehicle, comprising:
a load monitor configured to monitor whether a load in the eco-friendly vehicle is operated, wherein the current sensor is configured to sense an output current of a high voltage battery; and
a controller configured to detect an abnormality in the current sensor when the current sensor senses a current exceeding a first threshold value and the load is not operated.

2. The apparatus of diagnosing a current sensor of an eco-friendly vehicle according to claim 1, wherein the load is any one of a driving motor, a low voltage direct current (DC) to DC converter (LDC), an inverter, an air conditioner compressor, and an on-board charger.

3. The apparatus of diagnosing a current sensor of an eco-friendly vehicle according to claim 1, wherein the controller is configured to reset the current sensor in response to detecting the abnormality in the current sensor.

4. The apparatus of diagnosing a current sensor of an eco-friendly vehicle according to claim 1, further comprising:
a voltage sensor configured to sense a voltage of the high voltage battery.

5. The apparatus of diagnosing a current sensor of an eco-friendly vehicle according to claim 4, wherein the controller is configured to detect the abnormality in the load when a voltage variation of the high voltage battery exceeds a second threshold value for a threshold period of time and detect the abnormality in the current sensor when the voltage variation of the high voltage battery is less than the second threshold value for the threshold period of time, when the current sensor senses the current exceeding the first threshold value and the load is not operated.

6. The apparatus of diagnosing a current sensor of an eco-friendly vehicle according to claim 5, wherein the controller is configured to reset the current sensor in response to detecting the abnormality in the current sensor.

7. A method of diagnosing a current sensor of an eco-friendly vehicle, comprising:
monitoring, by a load monitor, whether a load in the eco-friendly vehicle is operated;
sensing, by the current sensor, an output current of a high voltage battery; and
detecting, by a controller, an abnormality in the current sensor when the current sensor senses a current exceeding a first threshold value and the load is not operated.

8. The method of diagnosing a current sensor of an eco-friendly vehicle according to claim 7, wherein the load is any one of a driving motor, a LDC, an inverter, an air conditioner compressor, and an on-board charger.

9. The method of diagnosing a current sensor of an eco-friendly vehicle according to claim 7, further comprising:
resetting, by the controller, the current sensor in response to detecting the abnormality in the current sensor.

10. A method of diagnosing a current sensor of an eco-friendly vehicle, comprising:
monitoring, by a load monitor, whether a load in the eco-friendly vehicle is operated;
sensing, by the current sensor, an output current of a high voltage battery;
sensing, by a voltage sensor, a voltage of the high voltage battery; and
detecting, by a controller, an abnormality in the current sensor based on the voltage sensed by the voltage sensor when the current sensor senses a current exceeding a first threshold value and the load is not operated.

11. The method of diagnosing a current sensor of an eco-friendly vehicle according to claim 10, wherein the detection includes:
monitoring, by the controller, a voltage variation of the high voltage battery for a threshold period of time when the current sensor senses the current exceeding the first threshold value and the load is not operated;
detecting, by the controller, the abnormality in the current sensor when the voltage variation is less than a second threshold value; and
detecting, by the controller, the abnormality in the load when the voltage variation exceeds the second threshold value.

12. The method of diagnosing a current sensor of an eco-friendly vehicle according to claim 11, further comprising:
resetting, by the controller, the current sensor in response to detecting the abnormality in the current sensor.
